(19) United States
(12) Patent Application Publication
(10) Pub. No.: US 2013/0299777 A1
(43) Pub. Date: Nov. 14, 2013

(54) LIGHT-EMITTING DIODES WITH LOW TEMPERATURE DEPENDENCE

(71) Applicant: THE REGENTS OF THE UNIVERSITY OF CALIFORNIA, Oakland, CA (US)

(72) Inventors: Shuji Nakamura, Santa Barbara, CA (US); Steven P. DenBaars, Goleta, CA (US); Daniel F. Feezell, Albuquerque, NM (US); James S. Speck, Goleta, CA (US); Chih-Chien Pan, Goleta, CA (US)

(73) Assignee: The Regents of the University of California, Oakland, CA (US)

(21) Appl. No.: 13/890,664

(22) Filed: May 9, 2013

Related U.S. Application Data
(60) Provisional application No. 61/644,808, filed on May 9, 2012.

(51) Int. Cl. H01L 33/16; H01L 33/00

(52) U.S. Cl. CPC H01L 33/16; H01L 33/0075
USPC 257/13; 438/46

(57) ABSTRACT

A III-nitride based LED with an External Quantum Efficiency (EQE) droop of less than 10% when a junction temperature of the LED is increased from 20 ° C. to at least 100 ° C. at a current density of the LED of at least 20 Amps per centimeter square.

### CROSS REFERENCE TO RELATED APPLICATIONS

This application claims priority under 35 U.S.C. §119(e) of the following co-pending and commonly-assigned U.S. Provisional Patent Application:

U.S. Provisional Patent Application Ser. No. 61/644,808, entitled “LIGHT-EMITTING DIODES WITH LOW TEMPERATURE DEPENDENCE,” filed on May 9, 2012, by Shuji Nakamura, Steven P. DenBaars, Daniel Feezell, James S. Speck, Chih-Chien Pan, attorney's docket number 30794.453.US-P1 (UC docket no. 2012-736-1), which application is incorporated by reference herein.

This application is related to the following co-pending and commonly-assigned U.S. patent application:

U.S. Utility application Ser. No. ______, filed on same date herewith, by Shuji Nakamura, Steven P. DenBaars, Daniel Feezell, James S. Speck, Chih-Chien Pan, and Shinichi Tanaka, entitled “HIGH OUTPUT POWER, HIGH EFFICIENCY BLUE LIGHT-EMITTING DIODES,” attorneys' docket number 30794.452-US-U1 (2012-736-2), which application claims priority under 35 U.S.C. §119(e) of U.S. Provisional Application Ser. No. 61/644,803, filed on May 9, 2012, by Shuji Nakamura, Steven P. DenBaars, Daniel Feezell, James S. Speck, Chih-Chien Pan, and Shinichi Tanaka, entitled “HIGH OUTPUT POWER, HIGH EFFICIENCY BLUE LIGHT-EMITTING DIODES,” attorneys' docket number 30794.452-US-P1 (2012-736-1), which application is incorporated by reference herein.

### BACKGROUND OF THE INVENTION

1. Field of the Invention

This invention relates to light-emitting diodes (LEDs) with low temperature dependence.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Gallium Nitride (GaN) based high-power and high-efficiency light-emitting diodes (LEDs) have increasingly become a dominant light source for illumination applications, such as auto-motive headlights, interior/exterior lighting, and full color displays. However, the reduction in light output power (LOP) or external quantum efficiency (EQE) as a function of current density (‘J-droop’) and junction temperature (‘T-droop’) limit the use of LEDs in various applications where high temperature operation is required. Proposed mechanisms explaining efficiency droop (‘J-droop’) are non-radiative Auger recombination, band-filling of localized states, and electron overflow. Therefore, several approaches may reduce or improve the J-droop. For instance, a large-area LED chip or a power chip design (chip size of ˜1 millimeter square (mm²)) have been used for LED products in order to have enough radiant flux by reducing the carrier concentrations as well as electron overflow. However, cost reduction has become a challenging issue in industry. In addition, polarization matched multiple quantum well (MQW) structures and nonpolar substrates may mitigate the J-droop. As for the T-droop, LEDs usually suffer from a strong decrease in LOP and EQE with increasing junction temperature. The junction temperature also plays an important role because it affects several properties of the LEDs, such as Shockley-Read-Hall, radiative, and Auger recombination, color stability, device lifetime, and phosphors quenching. Therefore, devices with low temperature dependence are highly desirable and required to maintain a consistent operating performance in LEDs.

The present invention discloses a semipolar (20-2-1) single-quantum-well (SQW) blue LED, with a relatively high characteristic temperature and Hot/Cold factor, and less EQE droop with increasing temperature, as compared to a polar (0001) multiple-quantum-well (MQW) blue LED.

### SUMMARY OF THE INVENTION

The present invention discloses LEDs or LED structures with a low temperature dependence, e.g., where the EQE and LOP of the LED have low temperature dependence.

For example, one or more embodiments of the invention disclose a Light Emitting Diode (LED), comprising a III-nitride based LED with an External Quantum Efficiency (EQE) droop of less than 10% when a junction temperature of the LED is increased from 20 degrees Celsius (° C.) to at least 100° C. at a current density of the LED of at least 20 Amps per centimeter square (A/cm²).

The LED can be a semipolar III-nitride LED.

The LEDs can be grown on semipolar (e.g., free-standing) GaN, or a semipolar plane of GaN, or on a GaN substrate (e.g., where the semipolar plane is (20-2-1). The active region of the LED structure, for emitting the light, can comprise one or more quantum wells or a single quantum well (SQW) (e.g., having the quantum well thickness thicker than 4 nm).

The LED can have less than 10% EQE droop with increasing temperature at different current densities. For example, the LED can have less than 10% EQE droop with increasing temperature (e.g., between 20 and 100° C.) at different current densities (e.g., between 20 and 100 A/cm²).

The LED can have a characteristic temperature of at least 800 Kelvin.

The semipolar LED can have a crystal quality, active region thickness, semipolar orientation, and structure such that the LOP or EQE droop is obtained.

The active region thickness can reduce the carrier density and the semipolar orientation of the LED can increase the crystal quality such that the LOP or the EQE is obtained.

The structure can include a number of quantum wells in the active region.

The structure can include a superlattice between the substrate and an active region of the LED, wherein the superlattice has a number of periods and composition such that the LOP and EQE is obtained.

The LED can further comprise a GaN substrate; an n-type GaN layer overlying a semipolar plane of the GaN substrate; the superlattice comprising an InGaN/GaN superlattice overlying the n-type GaN layer; the active region including an InGaN/GaN single quantum well overlying the InGaN/GaN superlattice; an AlGaN electron blocking layer overlying the single quantum well; a p-type GaN layer overlying the electron blocking layer; a transparent conductive contact layer overlying the p-type GaN layer; and metal contact to the n-type GaN layer.

The present invention further discloses a method of fabricating an LED, comprising growing a III-nitride based LED with an EQE droop of less than 10% when a junction temperature of the LED is increased from 20° C. to at least 100° C. at a current density of the LED of at least 20 A/cm².

### BRIEF DESCRIPTION OF THE DRAWINGS

Referring now to the drawings in which like reference numbers represent corresponding parts throughout:

FIG. 1 shows (a) a schematic figure of the semipolar (20-2-1) orientation in the wurtzite crystal structure, and (b) an LED structure on semipolar (20-2-1) free-standing GaN.

FIG. 2 plots EQE vs. current density under different temperatures for (a) a semipolar (20-2-1) SQW LED having the structure of FIGS. 1(b), and (b) a polar (0001) MQW LED, wherein the curves are for, from top to bottom, a temperature of 20°, 40, 60, 80, and 100° C., FIG. 2(c) plots forward voltage vs. Temperature for the semipolar (20-2-1) SQW blue LED [6], and FIG. 2(d) plots junction temperature vs. current density (A/cm²) for the semipolar (20-2-1) SQW blue LED [6], wherein the inset in FIG. 2(d) is thermal imaging of the semipolar (20-2-1) SQW blue LED at a current density of 100 A/cm².

FIG. 3 plots EQE vs. temperature under different current densities (ranging from 1 milliamp (mA) to 100 mA) for (a) a semipolar (20-2-1) SQW LED having the structure of FIGS. 1(b), and (b) a polar (0001) MQW LED, FIG. 3(c) plots EQE as a function of temperature for the semipolar (20-2-1) SQW blue LED [6], and FIG. 3(d) plots thermal droop as a function of temperature for the semipolar (20-2-1) blue LED [6].

FIG. 4 plots the characteristic temperature for a semipolar (20-2-1) SQW LED having the structure of FIG. 1(b), and for a polar (0001) MQW LED.

FIG. 5 plots the hot/cold factor as a function of current density for a semipolar SQW blue LED having the structure of FIG. 1(b), and for a polar MQW blue LED.

FIG. 6 is a flowchart illustrating a method of fabricating an LED.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Nomenclature

The terms “(AlInGaN)” “(In,Al)GaN”, or “GaN” as used herein (as well as the terms “III-nitride,” “Group-III nitride”, or “nitride,” used generally) refer to any alloy composition of the (Ga,Al,In,B)N semiconductors having the formula Ga_{w}AlₓIn_{y}B_{z}N where 0≦w≦1, 0≦x≦1, 0≦y≦1, 0≦z≦1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga,Al,In,B)N material species. Further, (Ga,Al,In,B)N materials within the scope of the invention may further include minor quantities of dopants and/or other impurity or inclusional materials.

Many (Ga,Al,In,B)N devices are grown along the polar c-plane of the crystal, although this results in an undesirable quantum-confined Stark effect (QCSE), due to the existence of strong piezoelectric and spontaneous polarizations. One approach to decreasing polarization effects in (Ga,Al,In,B)N devices is to grow the devices on nonpolar or semipolar planes of the crystal.

The term “nonpolar plane” includes the {11-20} planes, known collectively as a-planes, and the {10-10} planes, known collectively as m-planes. Such planes contain equal numbers of Group-III (e.g., gallium) and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero l Miller index. Subsequent semipolar layers are equivalent to one another, so the crystal will have reduced polarization along the growth direction.

Technical Description

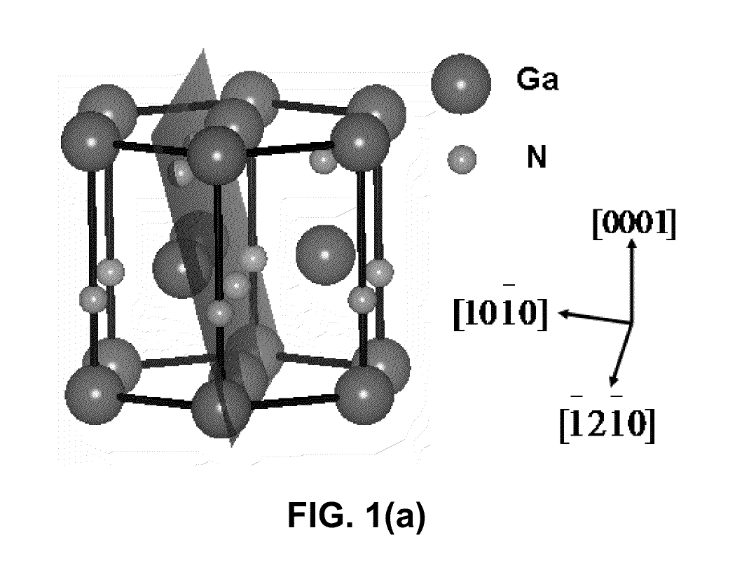

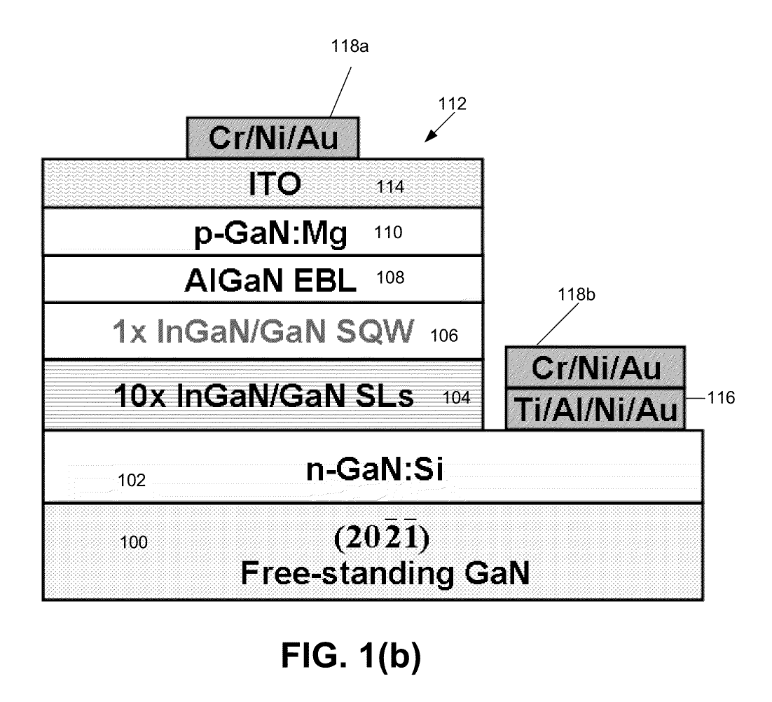

FIG. 1 shows (a) a schematic figure of a semipolar (20-2-1) orientation in the wurtzite crystal structure, and (b) an LED structure, which was homoexpitaxially grown on a free-standing semipolar (20-2-1) substrate 100 (having a 5×15 mm² surface area and a threading dislocation density of 10⁵-10⁶cm⁻²) using Metalorganic Chemical Vapor Deposition (MOCVD).

The structure comprises a 1 micrometer (μm) thick Si-doped GaN layer 102 with a Si doping concentration of 1×10¹⁹ cm⁻³, followed by a 10 period In_{0.01}Ga_{0.99}N/GaN (3/3 nm) superlattice (SL) 104, followed by a GaN/InGaN/GaN single quantum well (SQW) active region 106 comprising a 10 nm GaN bottom barrier, a 12 nm In_{0.16}Ga_{0.82}N quantum well, and a 15 nm GaN upper barrier. The SQW/barrier layer was followed by a 3 nm thick electron blocking layer (EBL) 108 with an Mg concentration of 2×10¹⁹ cm⁻³ and a 50 nm thick p-type GaN layer 110 with an Mg concentration of 4×10¹⁹ cm⁻³. The emission wavelength of the LED is 447 nm (blue light).

The LEDs were grown on semipolar (20-2-1) free-standing GaN substrates by atmospheric pressure metal organic chemical vapor deposition (MOCVD). The typical growth temperature was ˜1000° C. for the n-type GaN layer, with a V/III ratio (the ratio of NH₃ mole fraction to Trimethyl-Gallium mole fraction) of 3000. The active region was grown at a temperature of ˜850° C. with a V/III ratio of 12000. The n-type superlattice is grown at 900° C. and the EBL and p-type layer are grown at 960° C. All MOCVD growth was performed at atmospheric pressure (AP).

Subsequently, small-area (0.1 mm²) mesas 112 were formed by chlorine-based reactive ion etching. A 250 nm thick indium-tin-oxide (ITO) layer 114 was deposited by electron beam evaporation as the transparent p-contact, and Ti/Al/Ni/Au (10/100/10/100 nm) layers were deposited as the n-GaN contact 116. Finally, a thick Cr/Ni/Au metal stack of 25/20/500 nm was deposited on the ITO and the n-GaN contact to serve as the p-side wire bond pad 118a and n-side wire-bond pad 118b.

The present invention also fabricated, measured, and characterized a polar (0001) device having a similar LED structure to the semipolar (20-2-1) device, except the polar (0001) device had a 3-pair In_{0.18}Ga_{0.82}N/GaN (3.5/15 nm) active region and a 30-pair In_{0.01}Ga_{0.99}N/GaN (3/3 nm) SLs. Both the semipolar and polar devices have similar active region volume.

Un-encapsulated devices, mounted on a heat-dissipating ceramic plate, were tested in an integrating sphere under pulsed conditions to prevent self-heating. Device characterization was performed with forward currents up to 100 mA under varied ambient temperature from 20 to 100° C. [6]. Reference [6] also describes an embodiment of the present invention.

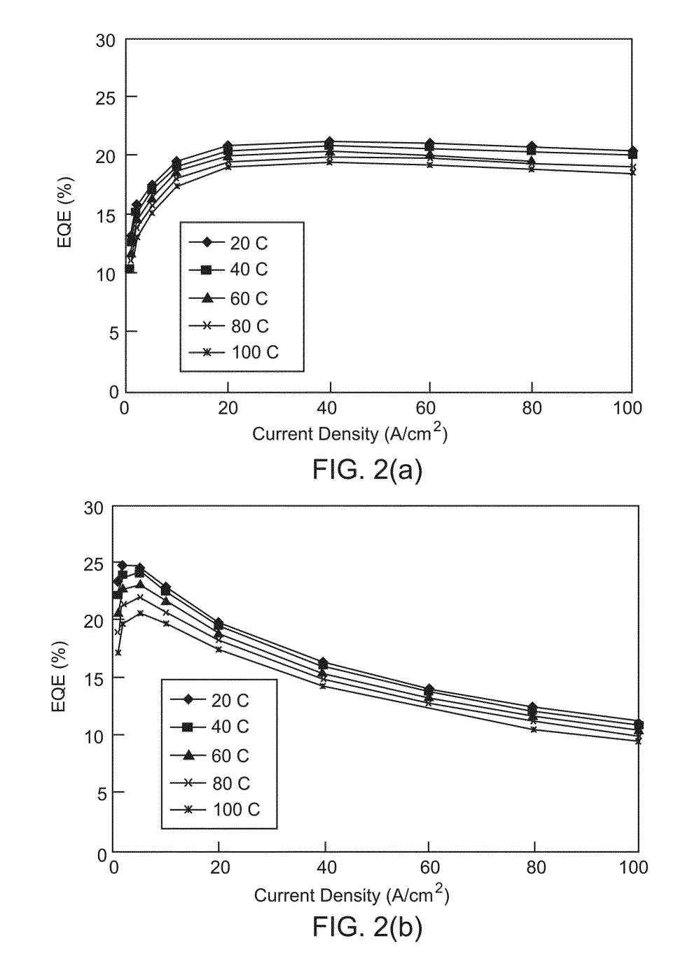

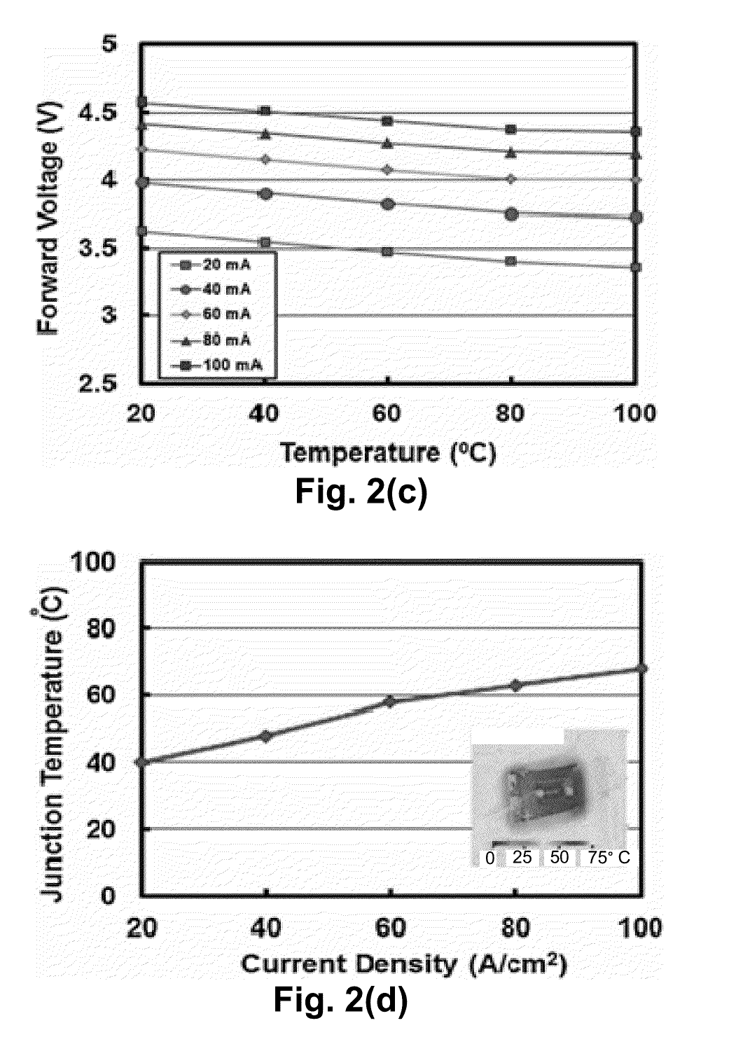

FIGS. 2(a) and (b) show the EQEs vs. current density for the semipolar (20-2-1) and polar (0001) blue LEDs under different temperatures, respectively.

FIG. 2(c) shows forward voltage V_{f} plotted as a function of temperature of the die and FIG. 2(d) shows junction temperature as a function of current density. The junction temperature can be extracted using dV_{f}/dT using the method described in [6]. The LED die temperature is also a good approximation of the junction temperature.

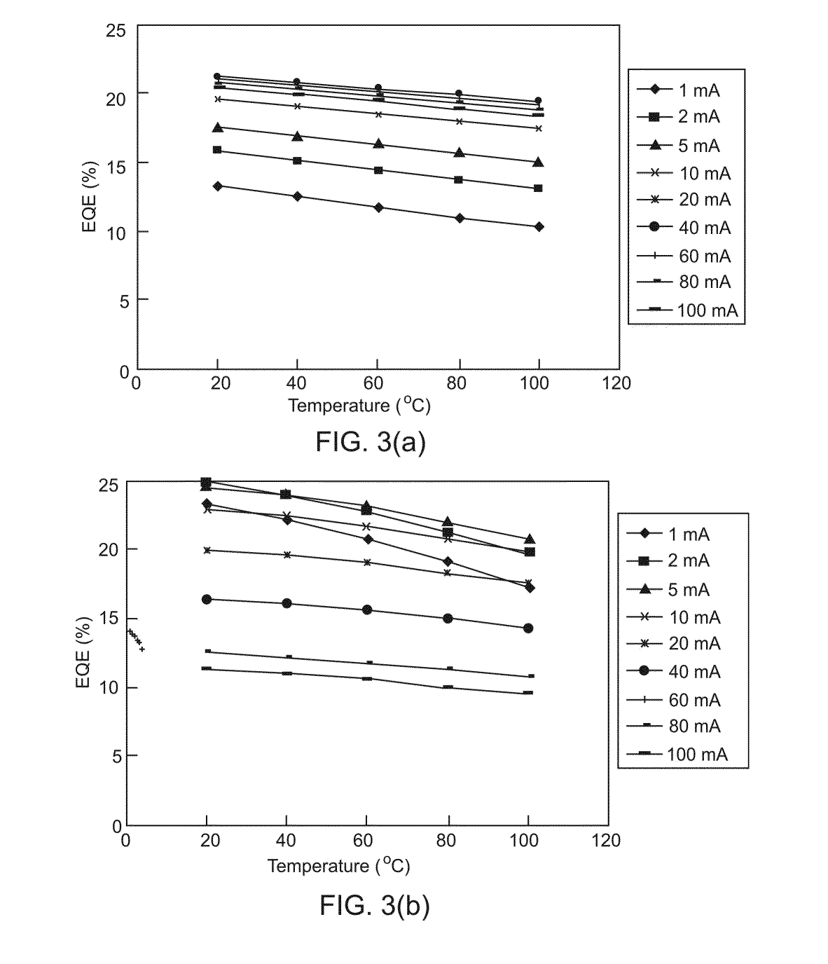

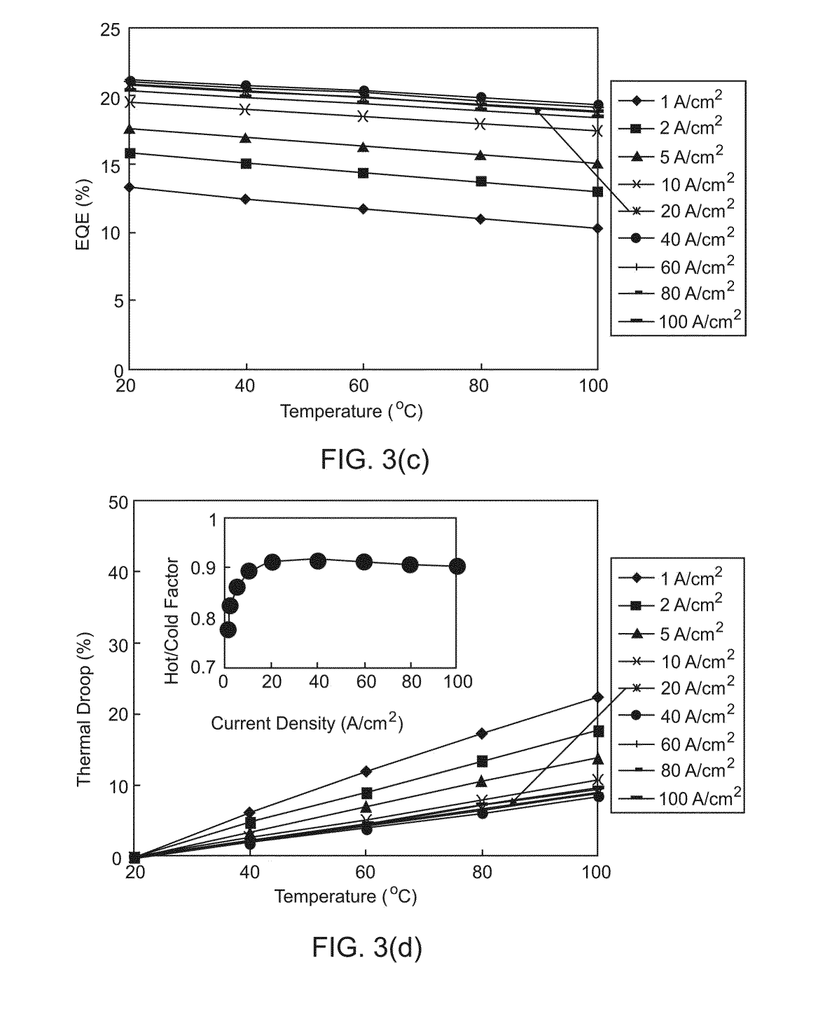

FIGS. 3(a) and (b) re-plot FIGS. 2(a) and (b) using junction temperature as the x-axis, and show the EQE vs. junction temperature for different current densities. FIG. 3(d) illustrates thermal droop.

The temperature dependence of the LOP can be described by the phenomenological equation:

$$I = {I}_{( 293 K )} exp ( - \frac{T - 293 K}{{T}_{C}} ) \qquad ( 1 )$$

where I are the LOPs or EQEs at different junction temperatures, and T_{C} is the characteristic temperature.

Generally, a high characteristic temperature T_{C} implies weak temperature dependence, in other words, LEDs will have less LOP or EQE droop with increasing temperature.

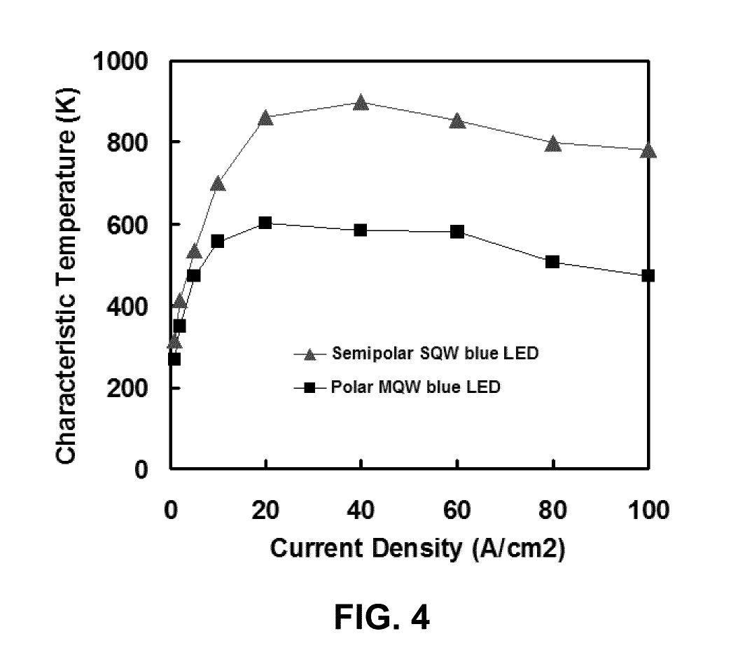

FIG. 4 show the characteristic temperatures for the semipolar (20-2-1) SQW LED and the polar (0001) MQW LED based on the calculations of equation (1). As can be seen in FIG. 4, the semipolar (20-2-1) SQW LED has higher characteristic temperatures than those of the polar (0001) MQW LED under different current densities, hence, a weak temperature dependence, or less LOP and EQE droop, can be expected in the semipolar (20-2-1) SQW LED.

The present invention also calculated the Hot/Cold factors for both the semipolar and polar devices. The Hot/Cold factor is defined as in equation (2):

$$Hot \text{/} Cold Factor = \frac{{I}_{100 ° C .}}{{I}_{20 ° C .}} \qquad ( 2 )$$

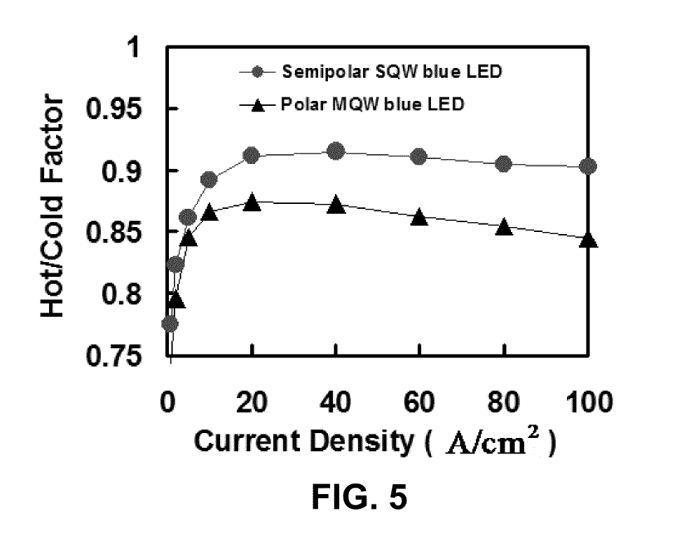

FIG. 5 shows the semipolar SQW LED also has higher Hot/Cold factors (>0.9 with current density above 20 A/cm²) than the polar MQW LED, which indicates that the semipolar SQW LED can have relatively small LOP and EQE droop compared to the polar MQW LED.

Process Steps

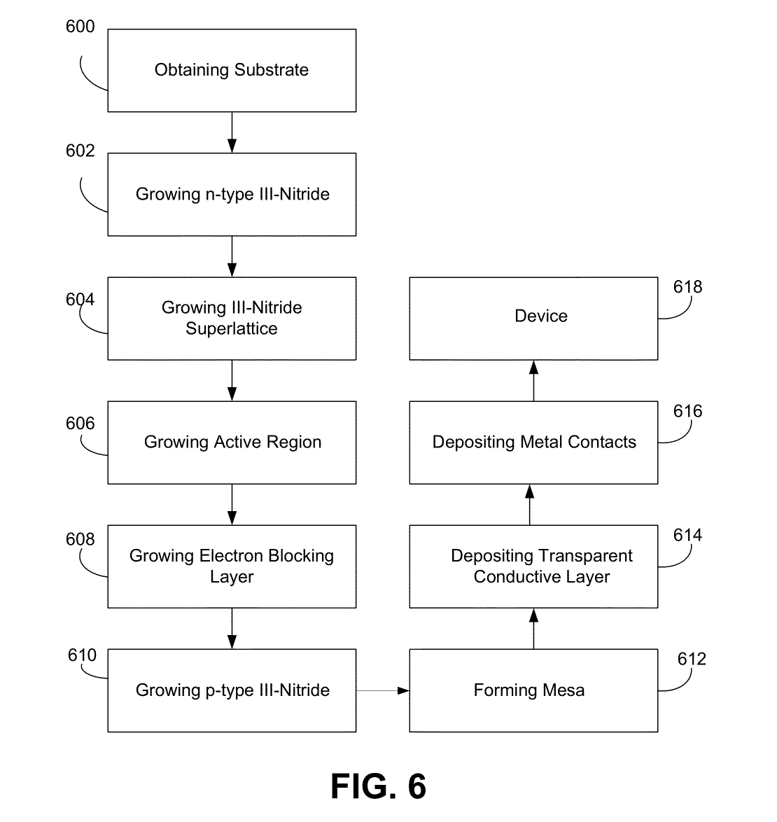

FIG. 6 illustrates a method of growing a III-nitride based LED with an EQE droop of less than 10% when a junction temperature of the LED is increased from 20° C. to at least 100° C. at a current density of the LED of 20 A/cm². For example, thermal droop defined as:

$$Thermal droop ( \% ) = \frac{{EQE ( J )}_{20 ° C .} - {EQE ( J )}_{100 ° C .}}{{EQE ( J )}_{20 ° C .}} \times 100 \%$$

and illustrated in FIG. 3(d), can be less than 10%, where EQE(J)_{20 ° C.} is EQE at the current density 20A/cm² and temperature of 20° C. and EQE(J)_{20 ° C.} is EQE at the current density 20A/cm² and temperature of 100° C.

The method can comprise the following steps (referring also to FIG. 1(b)).

Block 600 represents obtaining a substrate, such as a III-nitride (e.g., GaN) substrate or III-nitride/GaN template on a substrate. The device or LED can be grown on a semipolar plane, e.g., 20-2-1 plane, of the III-nitride substrate or template. The substrate can be a bulk or free standing substrate, such as free standing (20-2-1) GaN substrate 100. The III-nitride or GaN substrate can have a threading dislocation density less than 10⁶ cm⁻² for example.

Block 602 represents growing an n-type III-nitride (e.g., GaN 102) layer on or above or overlying a semipolar plane of the GaN substrate.

Block 604 represents growing a III-nitride superlattice (e.g., an InGaN/GaN superlattice 104) on or above or overlying the n-type III-nitride layer.

Block 606 represents growing a semipolar active region (e.g., InGaN/GaN SQW or InGaN quantum well with GaN barriers 106) on or above or overlying the superlattice.

Selecting the active region structure (e.g., the use of a single quantum well) can provide carrier uniformity (e.g., increase uniformity of the distribution of carriers, such as electrons, in the active region), and the active region thickness (e.g., using a larger thickness for the active region or quantum well, e.g., above 4 nm) can reduce the carrier density. A quantum well thickness of each QW or SQW can be thicker than 4 nm, for example.

However, one or more embodiments of the invention could use the structure having a number of quantum wells (multi quantum well structure) if the desired EQE, LOP, junction temperature, and/or characteristic temperature is obtained.

The active region can be such that a peak wavelength of the light emitted by the active region in response to the current density is in a blue spectrum or wavelength range (e.g., the active region can have a thickness, quantum well thickness, and composition, e.g., Indium composition, such that a peak wavelength of the light is in a blue spectrum or wavelength range). However, the active region can also emit light having peak wavelengths corresponding to other colors.

Block 608 represents growing an EBL (e.g., AlGaN 108) on or above or overlying the active region.

Block 610 represents growing a p-type III-nitride (e.g., GaN 110) layer on or above or overlying the EBL.

Block 612 represents forming a mesa 112 in the device layers 104-110. A top surface area of the mesa 112, or a top surface of the light emitting active region 106 of the LED, can be less than 1 mm², less than 0.2 mm², or no more than 0.1 mm², for example.

Block 614 represents depositing a transparent conductive contact layer (e.g., ITO 114) on or above or overlying the p-type III-nitride layer.

Block 616 represents depositing metal contacts on the n-type III-nitride layer and the transparent conductive contact layer.

Block 618 represents the end result, a III-nitride based LED, comprising a III-nitride based semipolar LED with an EQE droop of less than 10% when a junction temperature of the LED is increased from 20° C. to at least 100° C. at a current density of the LED of at least 20 A/cm². The current density can be between 20 and 100 A/cm² and/or the LED can have a characteristic temperature of at least 800 Kelvin.

One or more embodiments of the present invention are also described in related application U.S. Utility Application by Shuji Nakamura, Steven P. DenBaars, Daniel Feezell, James S. Speck, Chih-Chien Pan, and Shinichi Tanaka, entitled “HIGH OUTPUT POWER, HIGH EFFICIENCY BLUE LIGHT-EMITTING DIODES,” attorneys' docket number 30794.452-US-U1 (2012-736-2), which application is incorporated by reference herein.

The present invention has shown that the above unexpected and significantly improved EQE, junction temperature, and/or characteristic temperature can be achieved by selection of a combination of the layers/substrate/regions fabricated/obtained in Blocks 600-618. Specifically, the layers/substrate/regions fabricated/obtained in one or more of Blocks 600-618 can have a crystal quality (e.g., selection of substrate, threading dislocation density, stacking fault density, a semipolar plane or orientation and/or growth conditions) and structure (e.g., selection of an active region thickness, selection of a number of quantum wells such as a SQW, selection of a superlattice having a number of periods and a composition) such that the LED emits light with the above described significantly improved LOP and EQE (see also FIGS. 2-5).

In one embodiment, the selection includes an n-type GaN layer 102 overlying a semipolar plane (e.g., 20-2-1) of a bulk GaN substrate 100; a superlattice 104 comprising an InGaN/GaN superlattice 104 overlying the n-type GaN layer 102; an InGaN/GaN SQW 106 overlying the InGaN/GaN superlattice 104; an AlGaN EBL 108 overlying the SQW; a p-type GaN layer 110 overlying the EBL; a transparent conductive contact layer 114 overlying the p-type GaN layer 110; and metal contact 116 to the n-type GaN layer 102.

However, this is just one example of a selection or combination. The above LOP, EQE, junction temperature, and characteristic temperature could be achieved with other selections or combinations, or different combinations of one or more of the features or layers described in Blocks 600-618.

Possible Modifications

Different structures, well thickness, or peak wavelength, can be used. The LED can be a blue LED emitting blue light, or an LED emitting other wavelengths of light. Other semipolar planes or orientations could also be used.

The present invention can be applied to other optoelectronic devices, such as in a Laser or Laser Diode structure, solar cell, or transistor.

Advantages and Improvements

Commercial c-plane InGaN/GaN based high-brightness light-emitting diodes (LEDs) have attracted much attention because of their applications in mobile phones, back lighting, and general illumination. However, these commercial c-plane LEDs suffer from a big reduction in the light output power (LOP) and external quantum efficiency (EQE) due to the high device operating temperature. The LOP and EQE of these LEDs are sensitive to temperature, and these devices cannot tolerate a wide range of ambient temperatures. This is problematic for most commercial LED applications, where operation at temperatures beyond 100° C. is often required.

Therefore, due to the power roll-over observed in polar c-plane LEDs at high current densities and high junction temperatures, large-area (˜1 mm²) chips are typically required in high-power applications to reduce the average operating current density and increase the heat-dissipating area in order to mitigate the effects of efficiency (‘J-droop’) and temperature (‘T-droop’) droop.

Semipolar (20-2-1) GaN-based devices are promising for high efficiency LEDs because they exhibit very little Quantum Confined Stark Effect (QCSE), which increases the radiative recombination rate due to an increase in the electron-hole wave function overlap. In addition, semipolar (20-2-1) blue LEDs also exhibit narrower Full Width at Half Maximum (FWHM), and less blue shift compared to commercial c-plane blue LEDs at different current densities, which could contribute to a relatively high internal quantum efficiency because of a reduction of the band filling of localized states. Moreover, semipolar orientations permit the growth of wide quantum wells with thickness of more than 4 nanometers (nm) without any degradation of device performance. As a result, a reduction in the thermal efficiency droop is expected in semipolar (20-2-1) devices.

The present invention achieves high-efficiency and low-droop operation at high current densities (>100 A/cm²) and high junction temperatures (-100° C.), allowing the implementation of small-area (˜0.1 mm²) chips in high-power applications. This approach reduces the device footprint and ultimately leads to cost reductions.

The present invention demonstrates that a blue LED (chip size=0.1 mm²), comprising a 12 nm thick well, grown on the semipolar (20-2-1) plane, achieves a high characteristic temperature of ˜900 K at a current density of 40 A/cm². In the current density region from 20 to 100 Amps per centimeter square (A/cm²), the semipolar single-quantum-well (SQW) blue LED achieves a characteristic temperature of 250-300 Kelvin (K) more than that of polar multiple-quantum-well (MQW) blue LEDs. In addition, >90% Hot/Cold factors are also achieved in the current density region between 20 to 100 A/cm² for the semipolar SQW blue LED, resulting in less droop in LOP and EQE when increasing the temperature from 20 to 100° C. The present invention believes that the better LOP and EQE performance for the semipolar SQW LED under high operating temperature is due to the reduction in carrier leakage out of the active region and over the electron blocking layer. This is due to the wide active region (large volume=lower carrier density).

### REFERENCES

The following references are incorporated by reference herein.

1. David S. Meyaard et. al., “Temperature dependent efficiency droop . . . ,” Appl. Phys. Lett. 100, 081106 (2012).

2. Ya Ya Kudryk et. al., “Temperature-dependent efficiency droop . . . ,” Semicond. Sci. Technol. 27, 055013 (2012).

3. Chul Huh et. al., “Temperature dependence of light-output . . . ,” Proc. of SPIE 5187, 330 (2004).

4. Sameer Chhajed et. al., “Temperature-dependent light-output . . . ,” Phys. Status Solidi A 208, 947 (2011). 5. H. K. Lee et. al., “Thermal analysis and characterization . . . ,” Phys. Status Solidi A 208, 1497 (2010).

6. “Reduction in Thermal Droop Using Thick Single Quantum Well Structure in Semipolar (20-2-1) Blue Light Emitting Diodes”, Chih Chien Pan et. al., Applied Physics Express 5 (2012) 102103.

7. “High-Power, Low-Efficiency-droop Semipolar (20-2-1) Single-Quantum-Well Blue Light-Emitting Diodes,” by Chih-Chien Pan, Shinichi Tanaka, Feng Wu, Yuji Zhao, James S. Speck, Shuji Nakamura, Steven P. DenBaars, and Daniel Feezell, Appl. Physics Express 5 (2012), 062103-1.

8. High-Power, Low-Efficiency Droop Semipolar (20-2-1) Single-Quantum-Well Blue Light Emitting Diodes” by Chih-Chien Pan, Shinichi Tanaka, Feng Wu, Yuji Zhao, James S. Speck, Shuji Nakamura, Steven P. DenBaars, and Daniel Feezell, conference abstract submitted to International Symposium on Semiconductor Light Emitting Devices (ISSLED), conference dates Jul. 22^{nd} to 27^{th}, 2012.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A Light Emitting Diode (LED), comprising:
a III-nitride based LED with an External Quantum Efficiency (EQE) droop of less than 10% when a junction temperature of the LED is increased from 20° C. to at least 100° C. at a current density of the LED of 20 Amps per centimeter square (A/cm²).

2. The LED of claim 1, wherein the LED is grown on semipolar Gallium Nitride (GaN) or a semipolar plane of GaN substrate.

3. The LED of claim 2, further comprising an active region for emitting light, wherein the active region comprises one or more quantum wells having a thickness greater than 4 nanometers.

4. The LED of claim 3, wherein the semipolar plane is a (20-2-1) plane.

5. The LED of claim 3, wherein the active region comprises one quantum well or a single quantum well (SQW).

6. The LED In the claim 1, wherein the current density is between 20 and 100 A/cm².

7. The LED of claim 1, wherein the LED is a semipolar III-nitride LED.

8. The LED of claim 1, wherein the LED has a characteristic temperature of at least 800 Kelvin.

9. The LED of claim 1, wherein the III-nitride based LED is grown on a semipolar plane of a III-nitride substrate and the LED has a crystal quality, active region thickness, semipolar orientation, and structure such that the EQE droop is obtained.

10. The LED of claim 9, wherein the active region thickness reduces the carrier density and the semipolar orientation of the LED increases the crystal quality such that the LOP or the EQE is obtained.

11. The LED of claim 9, wherein the structure includes a number of quantum wells in the active region.

12. The LED of claim 9, wherein the structure includes a superlattice between the substrate and an active region of the LED, wherein the superlattice has a number of periods and composition such that the LOP and EQE is obtained.

13. The LED of claim 12, wherein the LED further comprises:
a GaN substrate;
an n-type GaN layer overlying a semipolar plane of the GaN substrate;
the superlattice comprising an InGaN/GaN superlattice overlying the n-type GaN layer;
the active region including an InGaN/GaN single quantum well overlying the InGaN/GaN superlattice;
an AlGaN electron blocking layer overlying the single quantum well;
a p-type GaN layer overlying the electron blocking layer;
a transparent conductive contact layer overlying the p-type GaN layer; and
metal contact to the n-type GaN layer.

14. A method of fabricating a Light Emitting Diode (LED), comprising:
growing a III-nitride based LED with an External Quantum Efficiency (EQE) droop of less than 10% when a junction temperature of the LED is increased from 20° C. to at least 100° C. at a current density of the LED of 20 Amps per centimeter square (A/cm²).

15. The method of claim 14, further comprising growing the LED under growth conditions and with a crystal quality, active region thickness, semipolar orientation, and structure such that the EQE droop is obtained.

16. The method of claim 15, wherein the LED is a semipolar LED grown on a semipolar plane of a bulk Gallium Nitride (GaN) substrate or on semipolar GaN.

17. The method of claim 16, wherein:
the semipolar plane is (20-2-1), and
an active region in the LED for emitting the light is a single quantum well (SQW).
